(19) United States
(12) Patent Application Publication
(10) Pub. No.: US 2026/0223427 A1
(43) Pub. Date: Jul. 30, 2026

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventors: Makoto SHIMOSAWA, Matsumoto-city (JP); Takaaki SUZAWA, Matsumoto-city (JP); Daisuke OZAKI, Matsumoto-city (JP)

(21) Appl. No.: 19/399,427

(22) Filed: Nov. 24, 2025

(30) Foreign Application Priority Data
Jan. 29, 2025 (JP) 2025-013328

(51) Int. Cl. H10D 64/23; H10D 12/00; H10D 12/01; H10D 62/10; H10D 62/60; H10D 64/27

(52) U.S. Cl. CPC H10D 64/232; H10D 12/038; H10D 12/481; H10D 62/126; H10D 62/60; H10D 64/518

(57) ABSTRACT

Provided is a semiconductor device including: a semiconductor substrate having an upper surface and a lower surface; an interlayer dielectric film which is provided on the upper surface of the semiconductor substrate and in which a contact hole is formed; a barrier metal provided inside the contact hole; and a contact plug which is, inside the contact hole, filled above the barrier metal. An angle formed by a side wall of the contact hole and an upper surface of the interlayer dielectric film is larger than 70° and smaller than 90°.

The contents of the following patent application(s) are incorporated herein by reference:

NO. 2025-013328 filed in JP on Jan. 29, 2025.

### BACKGROUND

### 1. Technical Field

The present invention relates to a semiconductor device and a manufacturing method of the semiconductor device.

### 2. Related Art

Patent Document 1 describes a manufacturing method by which “an electrode film 20 formed of a high-melting-point metal compound such as TiW, TiN, or TiWN is deposited on the insulating film 19 by sputtering, and further a Ti film and an Au film are sequentially vapor-deposited thereon, to form a low-resistance layer 21” (paragraph 0025). Patent Document 2 states: “By using a sputtering device, a 0.05-μm Ta (tantalum) film is subsequently formed on the entire surface of a semiconductor substrate from which the degradation layer 18 has been removed, and an improvement process layer 19 has been applied, so as to form a barrier layer 20 as shown in FIG. 2(g)” (paragraph 0034). Patent Document 3 describes a method for forming a semiconductor device by which “a barrier metal film 24 is formed on an interlayer dielectric film 22 along a profile of the contact opening 23” (paragraph 0025). Patent Document 4 discloses a method for forming a metal wiring for a semiconductor device “characterized in comprising: a step of forming an interlayer dielectric film on a semiconductor substrate having a predetermined structure formed; a step of forming a contact hole by etching the interlayer dielectric film; a step of forming a barrier metal layer on an inner surface of the contact hole, but determining a profile of the barrier metal layer by applying AC bias power; and a step of forming a contact plug so as to embed the contact hole and subsequently forming the metal wiring on an entire structure” (paragraph 0016).
Patent Document 1: Japanese Patent Application Publication No. H10-199896
Patent Document 2: Japanese Patent Application Publication No. 2002-170879
Patent Document 3: Japanese Patent Application Publication No. 2006-310752
Patent Document 4: Japanese Patent Application Publication No. 2003-203975
Patent Document 5: Japanese U.S. Pat. No. 4,191,900

### BRIEF DESCRIPTION OF THE DRAWINGS

FIG. 1 is a top view showing an example of a semiconductor device 100 according to an embodiment example.

FIG. 2 is a cross-sectional view showing an example of a cross section a-a′ in FIG. 1.

FIG. 3 is an enlarged diagram of a cross section of the semiconductor device 100.

FIG. 4A is a cross-sectional view showing a method for approximating an upper surface 51 of an interlayer dielectric film 38.

FIG. 4B is a cross-sectional view showing another method for approximating the upper surface 51 of the interlayer dielectric film 38.

FIG. 4C is a cross-sectional view showing yet another method for approximating the upper surface 51 of the interlayer dielectric film 38.

FIG. 5A is a cross-sectional view showing a method for approximating a side wall 55 of a contact hole 54.

FIG. 5B is a cross-sectional view showing another method for approximating the side wall 55 of the contact hole 54.

FIG. 5C is a cross-sectional view showing yet another method for approximating the side wall 55 of the contact hole 54.

FIG. 6 is a cross-sectional view showing yet another method for approximating the side wall 55 of the contact hole 54.

FIG. 7 is an enlarged diagram showing a vicinity of the interlayer dielectric film 38 in FIG. 3.

FIG. 8 is an enlarged diagram showing a vicinity of a contact hole 54 in FIG. 3.

FIG. 9 is an enlarged diagram showing another example of the vicinity of a contact hole 54 in FIG. 3.

FIG. 10 is an enlarged diagram showing yet another example of the vicinity of a contact hole 54 in FIG. 3.

FIG. 11 is a drawing showing an example of a manufacturing process of the semiconductor device 100.

FIG. 12A is a drawing showing an example of an upper surface side element structure forming step S100.

FIG. 12B is a drawing showing an example of an interlayer dielectric film forming step S102.

FIG. 12C is a drawing showing an example of a contact hole forming step S104.

FIG. 12D is a drawing showing an example of a barrier metal forming step S106.

FIG. 12E is a drawing showing an example of a contact portion forming step S108.

FIG. 12F is a drawing showing an example of a contact portion etching step S110.

FIG. 12G is a drawing showing an example of an electrode forming step S112.

FIG. 13 is a drawing showing an example of a barrier metal removing step S114.

FIG. 14A is a drawing showing a manufacturing process of the semiconductor device 100 in a comparative example.

FIG. 14B is a drawing showing the contact portion forming step S108 in a comparative example.

FIG. 14C is a drawing showing the contact portion etching step S110 in a comparative example.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solving means of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in implementation of a semiconductor device.

In the present specification, technical matters may be described by using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When a Z axis direction is described without describing the signs, it means that the direction is parallel to a +Z axis and a −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is an SI unit system unless otherwise noted. Although a unit of a length may be expressed in cm, various calculations may be performed after conversion to meters (m). Each concentration in the present invention may be a value at room temperature. As an example, a value at 300 K (Kelvin) (about 26.9 degrees C.) may be used as the value at room temperature.

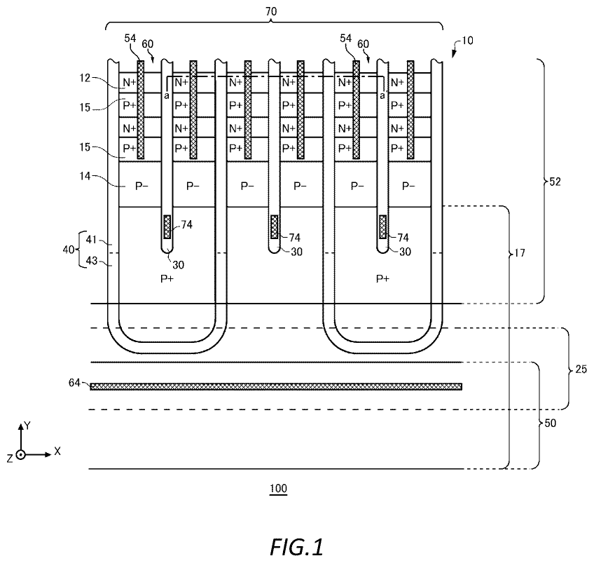

FIG. 1 is a top view showing an example of a semiconductor device 100 according to an embodiment example. The semiconductor device 100 in the present example is a semiconductor chip including a transistor portion 70. Note that the element included in the semiconductor device 100 is not limited to a transistor. The semiconductor device 100 may include a diode portion and may include both the transistor portion 70 and the diode portion. The semiconductor device 100 may be a power semiconductor device for controlling electric power or the like. A rated current of the semiconductor device 100 may be 1 A or more.

The transistor portion 70 is a region obtained by projecting a collector region provided on a back surface side of a semiconductor substrate 10 onto the upper surface of the semiconductor substrate 10. The collector region will be described below. The transistor portion 70 includes a transistor such as an IGBT. In the present example, the transistor portion 70 is an IGBT. Note that the transistor portion 70 may be another transistor such as a MOSFET.

The present drawing illustrates a region around an active portion of the semiconductor device 100, and other regions are omitted. For example, an edge termination structure portion may be provided in a region on a negative side in the Y axis direction in the semiconductor device 100 in the present example. The edge termination structure portion reduces electric field strength on the upper surface side of the semiconductor substrate 10. For example, the edge termination structure portion has a structure of a guard ring, a field plate, a RESURF, and a combination thereof. Note that although the present example describes an edge on the negative side in the Y axis direction for convenience, the same applies to other edges of the semiconductor device 100.

The semiconductor substrate 10 is a substrate which is formed of a semiconductor material. The semiconductor substrate 10 may be a silicon substrate or may be a silicon carbide substrate. The semiconductor substrate 10 in the present example is the silicon substrate. Note that when simply referred to as a top view in the present specification, it means that the semiconductor substrate 10 is viewed from the upper surface side. As explained later, the semiconductor substrate 10 has an upper surface and a lower surface.

The semiconductor device 100 in the present example includes, at the upper surface of the semiconductor substrate 10, gate trench portions 40, an emitter region 12, a base region 14, and a well region 17. The semiconductor device 100 may further include dummy trench portions 30 and may further include a contact region 15. Also, the semiconductor device 100 of the present example includes an emitter electrode 52 and a gate metal layer 50 provided above the upper surface of the semiconductor substrate 10. The gate trench portions 40 are an example of a MOS gate structure provided in the semiconductor device 100.

The emitter electrode 52 is provided above the gate trench portions 40, the dummy trench portions 30, the emitter region 12, the base region 14, the contact region 15, and the well region 17. In addition, the gate metal layer 50 is provided above a connection portion 25 and the well region 17.

The emitter electrode 52 and the gate metal layer 50 are formed of a material containing metal. At least a partial region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate metal layer 50 may be formed of metal such as aluminum (Al) or of a metal alloy such as an aluminum-silicon alloy (AlSi) or an aluminum-silicon-copper alloy (AlSiCu). The emitter electrode 52 and the gate metal layer 50 may have a barrier metal formed of titanium, a titanium compound, or the like under a region formed of aluminum and the like. The barrier metal will be explained later. The emitter electrode 52 and the gate metal layer 50 are provided separated from each other.

The emitter electrode 52 and the gate metal layer 50 are provided above the semiconductor substrate 10 with an interlayer dielectric film interposed therebetween. The interlayer dielectric film is omitted from FIG. 1. A contact hole 54, a contact hole 64, and a contact hole 74 are provided to penetrate the interlayer dielectric film.

The contact hole 64 electrically connects the gate metal layer 50 and a gate conductive portion in the transistor portion 70 via the connection portion 25. Inside the contact hole 64, a contact plug formed of tungsten or the like may be formed. The contact plug will be explained later.

The contact hole 74 connects the emitter electrode 52 with dummy conductive portions within the dummy trench portions 30. Inside the contact hole 74, a contact plug formed of tungsten or the like may be formed.

One end of the connection portion 25 is connected to the gate metal layer 50. The connection portion 25 in the present example is provided so as to extend in the X axis direction, and another end is electrically connected to the gate conductive portion. The connection portion 25 is a conductive material such as polysilicon doped with impurities. The connection portion 25 in the present example is polysilicon (N+) doped with impurities of the N type. The connection portion 25 is provided above the upper surface of the semiconductor substrate 10, via an insulating film or the like such as an oxidized film.

The gate trench portions 40 are an example of a plurality of trench portions extending in a predetermined extending direction, on the upper surface side of the semiconductor substrate 10. The gate trench portions 40 are arrayed at a predetermined interval along a predetermined array direction (the X axis direction in the present example). The gate trench portion 40 in the present example includes two extending parts 41 which extend along an extending direction (the Y axis direction in the present example) parallel to the upper surface of the semiconductor substrate 10 and perpendicular to the array direction and a connecting part 43 which connects the two extending parts 41.

At least a part of the connecting part 43 is preferably formed in a curved shape. Connecting end portions of the two extending parts 41 of the gate trench portion 40 can reduce electric field strength at the end portions of the extending parts 41. In the connecting part 43 of the gate trench portion 40, the gate conductive portion may electrically be connected to the gate metal layer 50 via the connection portion 25.

The dummy trench portions 30 are an example of a plurality of trench portions extending in a predetermined extending direction, on the upper surface side of the semiconductor substrate 10. The dummy trench portion 30 is a trench portion which is electrically connected to the emitter electrode 52. Similarly to the gate trench portions 40, the dummy trench portions 30 are arrayed at a predetermined interval along a predetermined array direction (the X axis direction in the present example). Although having I-shapes at the upper surface of the semiconductor substrate 10 in the present example, the dummy trench portions 30 may have U-shapes at the upper surface of the semiconductor substrate 10, similarly to the gate trench portions 40. That is, the dummy trench portion 30 may include two extending parts extending along an extending direction and a connecting part connecting the two extending parts.

The transistor portion 70 in the present example has a structure in which two gate trench portions 40 and two dummy trench portions 30 are repeatedly arrayed. That is, the transistor portion 70 in the present example has the gate trench portions 40 and the dummy trench portions 30 at a ratio of 1:1. For example, the transistor portion 70 has one dummy trench portion 30 between two extending parts 41.

It is to be noted that the ratio between the gate trench portions 40 and the dummy trench portions 30 is not limited to that in the present example. A ratio of the gate trench portions 40 may be larger than a ratio of the dummy trench portions 30, or the ratio of the dummy trench portions 30 may be larger than the ratio of the gate trench portions 40. The ratio between the gate trench portions 40 and the dummy trench portions 30 may be 2:3, or may be 2:4. In addition, the transistor portion 70 may not include the dummy trench portions 30 with all trench portions being the gate trench portions 40. Furthermore, in the case where the diode portion is provided, the diode portion may be provided only with the dummy trench portions 30.

The well region 17 is a region of a second conductivity type provided on the side of the upper surface of the semiconductor substrate 10 relative to a drift region explained later. The well region 17 is an example of a well region provided in a peripheral side of the active portion. The well region 17 is of the P+ type as an example. The well region 17 is formed in a predetermined range from a region overlapping with the gate metal layer 50 toward the active portion in a top view. A diffusion depth of the well region 17 may be deeper than a depth of the gate trench portion 40 and the dummy trench portion 30. Partial regions of the gate trench portion 40 and the dummy trench portion 30 on a gate metal layer 50 side are formed in the well region 17. Bottoms of ends in the extending direction of the gate trench portion 40 and the dummy trench portion 30 may be covered with the well region 17.

The active portion may be a region of the semiconductor substrate 10 where a principal current flows. The active portion may be a region surrounded by the well region 17 in a top view. The active portion may be a region overlapping with a high concentration region explained later and may be a region in which high concentration regions are periodically arranged. In a diode, the active portion may be a region overlapping with an anode region.

The contact hole 54 is formed above each region of the emitter region 12 and the contact region 15 in the transistor portion 70. The contact hole 54 is not provided above the well regions 17 provided at both ends in the Y axis direction. In this manner, one or more contact holes 54 are formed in the interlayer dielectric film. In a top view, the contact hole 54 may be circular, may have a grid-like shape, may be provided so as to extend in a predetermined direction, and may discretely be provided in plurality in a predetermined direction. The same applies to the contact hole 64 and the contact hole 74. The contact hole 54 in the present example extends in the extending direction of the trench portion.

The mesa portion 60 is a region of the semiconductor substrate 10 that is sandwiched between the trench portions in the array direction of the trench portions. A depth of the mesa portion 60 may be a part from the upper surface of the semiconductor substrate 10 to the depth of the deepest bottom portion of the trench portions. The extending part of each trench portion may be defined as one trench portion. That is, a region sandwiched between two extending parts may be defined as the mesa portion 60.

The mesa portion 60 is provided so as to be in direct contact with at least one of the dummy trench portion 30 or the gate trench portion 40 in the transistor portion 70. At the upper surface of the semiconductor substrate 10, the mesa portion 60 has the well region 17, the emitter region 12, the base region 14, and the contact region 15. In the mesa portion 60, the emitter regions 12 and the contact regions 15 are alternately provided in an extending direction.

The base region 14 is a second conductivity type region provided on the upper surface side of the semiconductor substrate 10. The base region 14 is of the P-type as an example. At the upper surface of the semiconductor substrate 10, the base region 14 may be provided in both end portions, in the Y axis direction, of the mesa portion 60. It should be noted that FIG. 1 shows only one end portion of the base region 14 in the Y axis direction. Further, although the base region 14 is also provided below the emitter region 12 and the contact region 15, illustration thereof is omitted from FIG. 1.

The emitter region 12 is a region of a first conductivity type which has a doping concentration higher than that of the drift region. The emitter region 12 in the present example is of the N+ type as an example. Examples of a dopant of the emitter region 12 include arsenic (As). The emitter region 12 is provided in contact with the gate trench portions 40, at an upper surface of the mesa portion 60. The emitter region 12 may be provided to extend in the X axis direction from one to another of two trench portions sandwiching the mesa portion 60. The emitter region 12 is also provided below the contact hole 54.

In addition, the emitter region 12 may or may not be in contact with the dummy trench portion 30. The emitter region 12 in the present example is in contact with the dummy trench portion 30.

The contact region 15 is a region of the second conductivity type which is provided above the base region 14 and has a doping concentration higher than that of the base region 14. The contact region 15 in the present example is of the P+type as an example. The contact region 15 in the present example is provided in the upper surface of the mesa portion 60. The contact region 15 may be provided in the X axis direction from one to another of the two trench portions sandwiching the mesa portion 60. The contact region 15 may or may not be in contact with the gate trench portion 40 or the dummy trench portion 30. The contact region 15 in the present example is in contact with the dummy trench portion 30 and the gate trench portion 40. The contact region 15 is also provided below the contact hole 54.

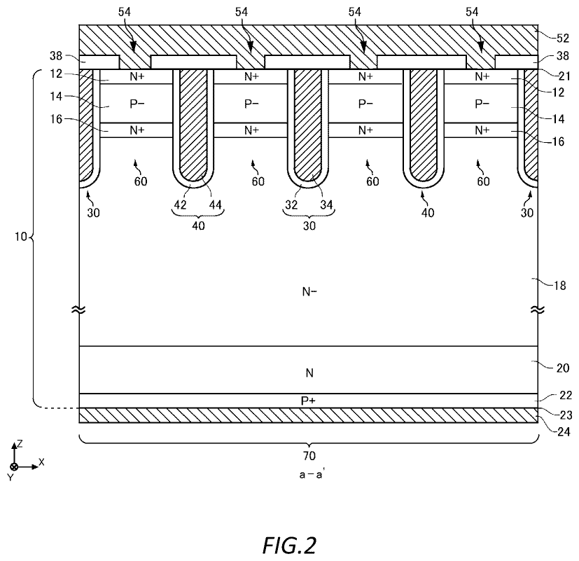

FIG. 2 is a cross-sectional view showing an example of a cross section a-a′ in FIG. 1. The cross section a-a′ is an XZ plane which passes through the emitter region 12 in the transistor portion 70. The semiconductor device 100 in the present example includes the semiconductor substrate 10, an interlayer dielectric film 38, the emitter electrode 52, and a collector electrode 24 in the cross section a-a′. The emitter electrode 52 is formed on the upper surface 21 of the semiconductor substrate 10 and above the interlayer dielectric film 38.

The drift region 18 is a region of the first conductivity type which is provided in the semiconductor substrate 10. The drift region 18 of the present example is of the N− type, as an example. The drift region 18 may be a region in the semiconductor substrate 10 which has remained without other doping regions formed. That is, a doping concentration of the drift region 18 may be a doping concentration of the semiconductor substrate 10.

The buffer region 20 is a region of the first conductivity type provided on the side of a lower surface 23 of the semiconductor substrate 10 relative to the drift region 18. The buffer region 20 in the present example is of the N type as an example. A doping concentration of the buffer region 20 is higher than the doping concentration of the drift region 18. The buffer region 20 may function as a field stop layer which prevents a depletion layer extending from a lower surface side of the base region 14 from reaching the collector region 22 of the second conductivity type. Note that the buffer region 20 may be omitted.

The collector region 22 is provided below the buffer region 20 in the transistor portion 70. The collector region 22 is of the second conductivity type. The collector region 22 in the present example is of the P+type as an example.

The collector electrode 24 is formed on the lower surface 23 of the semiconductor substrate 10. The collector electrode 24 is formed of a conductive material such as metal. The material of the collector electrode 24 may be the same as or different from the material of the emitter electrode 52.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided above the base region 14. The emitter region 12 is exposed at the upper surface 21 of the semiconductor substrate 10. The emitter region 12 is provided in contact with the gate trench portion 40. The emitter region 12 may or may not be in contact with the dummy trench portion 30. The emitter region 12 is an example of a high concentration region. For example, in the case where the semiconductor device 100 includes a MOSFET, a source region may be provided as a high concentration region.

The accumulation region 16 is a region of the first conductivity type provided on the side of the upper surface 21 of the semiconductor substrate 10 relative to the drift region 18. The accumulation region 16 in the present example is provided between the drift region 18 and the base regions 14. The accumulation region 16 is of the N+ type as an example. Note that the accumulation region 16 may not be provided.

The accumulation region 16 is provided in contact with the gate trench portion 40. The accumulation region 16 may or may not be in contact with the dummy trench portion 30. A doping concentration of the accumulation region 16 is higher than the doping concentration of the drift region 18. Providing the accumulation region 16 can increase a carrier injection enhancement effect (IE effect) to reduce an on-voltage of the transistor portion 70.

One or more gate trench portions 40 and one or more dummy trench portions 30 are provided from the upper surface 21 of the semiconductor substrate 10 toward an inside of the semiconductor substrate 10. Each trench portion is provided from the upper surface 21 through the drift region 18. In a region provided with at least one of the emitter region 12, the base region 14, the contact region 15, or the accumulation region 16, each trench portion also penetrates these regions to reach the drift region 18. A structure in which the trench portion passes through the doping region is not limited to a structure which is made by forming the doping region and then forming the trench portion in order. The configuration of the trench portion penetrating the doping region includes a configuration of the doping region being formed between the trench portions after forming the trench portion.

The gate trench portion 40 has a gate trench, a gate insulating film 42, and a gate conductive portion 44 which are formed on the upper surface 21. The gate insulating film 42 is formed to cover an inner wall of the gate trench. The gate insulating film 42 may be formed by oxidizing or nitriding a semiconductor on the inner wall of the gate trench. The gate conductive portion 44 is formed farther inward than the gate insulating film 42 within the gate trench. The gate insulating film 42 insulates the gate conductive portion 44 from the semiconductor substrate 10. The gate conductive portion 44 is formed of a conductive material such as polysilicon. The gate trench portion 40 is covered by the interlayer dielectric film 38 at the upper surface 21.

The gate conductive portion 44 includes a region opposing the adjacent base region 14 on a mesa portion 60 side with the gate insulating film 42 interposed therebetween, in the depth direction of the semiconductor substrate 10. When a predetermined voltage is applied to the gate conductive portion 44, a channel with an electron inversion layer is formed in a surface layer of an interface of the base region 14 which is in contact with the gate trench. The base region 14 is an example of a channel region, which is a region in which a channel is formed.

The dummy trench portion 30 may have the same structure as that of the gate trench portion 40. The dummy trench portion 30 has a dummy trench, a dummy insulating film 32, and a dummy conductive portion 34 which are formed on the upper surface 21 side. The dummy insulating film 32 is formed to cover an inner wall of the dummy trench. The dummy conductive portion 34 is formed within the dummy trench, and is formed farther inward than the dummy insulating film 32. The dummy insulating film 32 insulates the dummy conductive portion 34 from the semiconductor substrate 10. The dummy conductive portion 34 may electrically be connected to the emitter electrode 52 via the contact hole 74 shown in FIG. 1. The dummy trench portion 30 may be covered with the interlayer dielectric film 38 at the upper surface 21.

In the present specification, the gate conductive portion 44 and the dummy conductive portion 34 may collectively be referred to as a trench conductive portion. The trench conductive portion is a conductive part which is provided inside a trench and to which a predetermined voltage (gate voltage or voltage of the emitter electrode 52, or the like) is applied from outside. Note that it is acceptable when the trench conductive portion includes at least one of the gate conductive portion 44 or the dummy conductive portion 34. Further, the trench conductive portion may be floating potentially. Further, in the present specification, the gate insulating film 42 and the dummy insulating film 32 may collectively be referred to as a trench insulating film. The trench insulating film insulates the trench conductive portion from the semiconductor substrate 10.

The interlayer dielectric film 38 is provided above the semiconductor substrate 10. A lower surface of the interlayer dielectric film 38 in the present example is in contact with the upper surface 21 of the semiconductor substrate 10. The emitter electrode 52 is provided above the interlayer dielectric film 38. The interlayer dielectric film 38 is provided with the one or more contact holes 54 electrically connecting the emitter electrode 52 and the semiconductor substrate 10. Similarly, the contact hole 64 and the contact hole 74 may be provided penetrating the interlayer dielectric film 38.

The interlayer dielectric film 38 may be a silicon oxide film. The interlayer dielectric film 38 may be a boro-phospho silicate glass (BPSG) film, may be a borosilicate glass (BSG) film, or may be a phosphosilicate glass (PSG) film. The interlayer dielectric film 38 may also include a high temperature silicon oxide (HTO: High Temperature Oxide) film.

In FIG. 2, shapes of the interlayer dielectric film 38 and the contact holes 54 are schematically depicted to explain an outline. Details of the shapes of the interlayer dielectric film 38 and the contact holes 54 will be explained later. Further, as explained later, the barrier metal and the contact plugs are formed below (the negative side in the Z axis direction) the emitter electrode 52.

The semiconductor device 100 in the present example has a vertical semiconductor structure in which a back surface side metal layer (the collector electrode 24) is provided on the lower surface 23 side of the semiconductor substrate 10. However, the semiconductor device 100 may have a horizontal semiconductor structure in which no metal layer is provided on the lower surface 23 side. Note that, in the present example, an IGBT having a trench gate structure is explained as an example of the semiconductor device 100. It should be noted that the semiconductor device 100 may be a semiconductor device 100 having a planar gate structure, or may be another semiconductor device 100 such as a diode. The semiconductor device 100 may include a MOSFET of an N channel, or may include a MOSFET of a P channel.

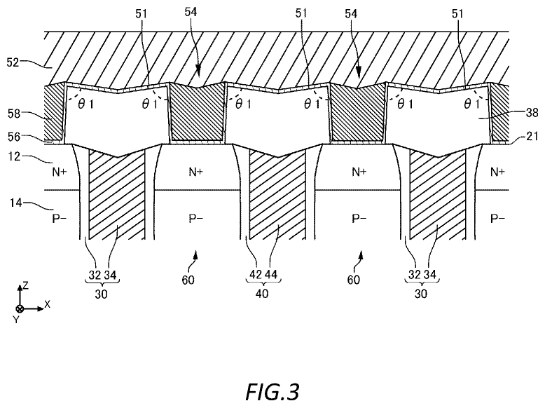

FIG. 3 is an enlarged diagram of a cross section of the semiconductor device 100. The present example presents the enlarged diagram of the cross section in a vicinity of the interlayer dielectric film 38 and the contact holes 54. The cross section in the present example is an XZ cross section which passes through the emitter region 12 at the upper surface 21 of the semiconductor substrate 10. In addition to the configuration explained with FIG. 2, the semiconductor device 100 includes a barrier metal 56 and contact plugs 58.

Note that, in the present specification, the structure or the like in a vicinity of contact holes may be explained by using the contact holes 54; however, a similar structure or the like may be applied to other contact holes such as the contact holes 64 and the contact holes 74. In other words, the barrier metal 56 and the contact plug 58 may be provided for other contact holes such as the contact holes 64 and the contact holes 74. The shape of the interlayer dielectric film 38 explained later may similarly be applied to other contact holes.

The barrier metal 56 is provided inside the contact holes 54. The barrier metal 56 in the present example is provided inside the contact holes 54 and along an upper surface 51 of the interlayer dielectric film 38. In other words, the barrier metal 56 provided in one contact hole 54 and the barrier metal 56 provided in another contact hole 54 are connected by the barrier metal 56 provided along the upper surface 51 of the interlayer dielectric film 38.

In an example, the barrier metal 56 is a film containing at least one of titanium (Ti), tantalum (Ta), titanium nitride (TiN), or tantalum nitride (TaN). By providing the barrier metal 56, it is possible, even in the case where a defect or the like occurred inside the emitter electrode 52, to prevent ions in resin or a protective film encapsulating the semiconductor device 100 from spreading onto the semiconductor substrate 10 through the defect. In addition, it is possible to prevent the contact plugs 58 and the semiconductor substrate 10 from being in contact with each other.

The barrier metal 56 is formed along the shapes of the contact holes 54 and the interlayer dielectric film 38 in surroundings thereof. Inside the contact holes 54, the barrier metal 56 is in contact with the upper surface 21 of the semiconductor substrate 10. At least a part of the barrier metal 56 in a part in contact with the upper surface 21 may be silicidized to form titanium silicide.

Inside the contact hole 54, the contact plug 58 is provided above the barrier metal 56. The contact plug 58 is in contact with the barrier metal 56. The contact plug 58 is a conductive material filled inside the contact hole 54. For having an excellent embedding property, the contact plug 58 is able to fill the inside of the contact hole 54, even when the contact hole 54 has a small width. The width of the contact hole 54 may be equal to or smaller than 0.5 μm and may be equal to or larger than 0.05 μm. The contact plug 58 may account for a volume equal to or larger than 50% of the inside of the contact hole 54, may account for a volume equal to or larger than 70%, and may account for a volume equal to or larger than 90%.

The contact plug 58 may be of a material different from that of the emitter electrode 52. For example, the material of the contact plug 58 may be tungsten. The material of the contact plug 58 may be molybdenum. An upper surface of the contact plug 58 is in contact with the emitter electrode 52. In other words, the emitter electrode 52 in the present example is electrically connected to the semiconductor substrate 10 via the contact plug 58 and the barrier metal 56. A part of the contact plug 58 may be positioned higher than the contact hole 54.

An angle formed by a side wall of a contact hole 54 and the upper surface 51 of the interlayer dielectric film 38 will be expressed as θ1. The angle θ1 in the present example is the angle formed by the side wall of the contact hole 54 and the upper surface 51 of the interlayer dielectric film 38 on the XZ cross section. In the case where the contact hole 54 is longitudinal in the Y axis direction, the angle θ1 may be measured at a center position of the contact hole 54 in the Y axis direction. Alternatively, the angle θ1 may be measured on the XZ cross section passing through the emitter region 12. With respect to at least one of the contact holes 54, the angle θ1 may satisfy the condition described below. With respect to all the contact holes 54 provided with the barrier metal 56, the angle θ1 may satisfy the condition described below. As shown in FIG. 3, one contact hole 54 has two corner portions on the XZ cross section. Accordingly, one contact hole 54 corresponds to two angles θ1. Of the two angles θ1, at least one of the angles θ1 may satisfy the condition described below, and both of the angles θ1 may satisfy the condition described below.

The angle θ1 in the present example is smaller than 90°. The reasons is, as explained later in detail, that a dip of the trench conductive portion is reflected on the interlayer dielectric film 38 in FIG. 3, and the upper surface 51 of the interlayer dielectric film 38 thus has a dip. Note that, in another example, the angle θ1 may be smaller than 90° also in the case where the contact hole 54 has a so-called inversely-tapered shape so that cross-sectional areas thereof increase downward. In other words, the angle θ1 is smaller than 90° in situations where, in a vicinity of the contact hole 54, the position of the upper surface 51 of the interlayer dielectric film 38 becomes lower as the distance from the contact hole 54 increases or where the contact hole 54 has an inversely-tapered shape.

The angle θ1 in the present example is larger than 70°. With this configuration, as explained later, it is possible, in a manufacturing process of the semiconductor device 100, to inhibit delamination of the barrier metal 56 which may occur at a corner of the interlayer dielectric film 38 (a point at which the side wall of the contact hole 54 intersects the upper surface 51 of the interlayer dielectric film 38).

The angle θ1 may be larger than 72°, may be larger than 74°, may be larger than 76°, may be larger than 78°, may be larger than 80°, may be larger than 82°, or may be larger than 84°. The angle θ1 may be smaller than 88°, may be smaller than 86°, may be smaller than 84°, may be smaller than 82°, or may be smaller than 80°. A lower limit value and an upper limit value may each arbitrarily be combined in a range causing no conflict.

FIG. 3 describes an example using the contact hole 54; however, the angle θ1 may be in the range described above, with respect to other contact holes such as the contact holes 64 or the contact holes 74 shown in FIG. 1, or the like. Further, the contact hole having the angle θ1 may be provided in the active portion of the semiconductor substrate 10 or may be provided in a location (e.g., the edge termination structure portion described above) other than the active portion. At least a part of the contact hole having the angle θ1 may be provided above the emitter region 12, may be provided above the contact region 15, may be provided above the dummy trench portion 30, may be provided above the gate trench portion 40, may be provided above the connection portion 25, may be provided above the well region 17, and may be provided above a guard ring of the edge termination structure portion. In FIG. 3, at least a part of the contact hole 54 having the angle θ1 is provided above the emitter region 12. Further, the barrier metal 56 and the contact plug 58 may also be provided for other contact holes.

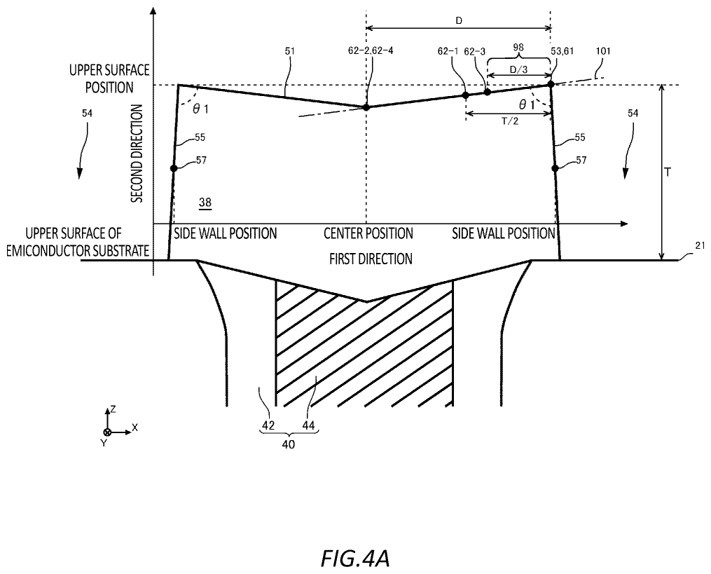

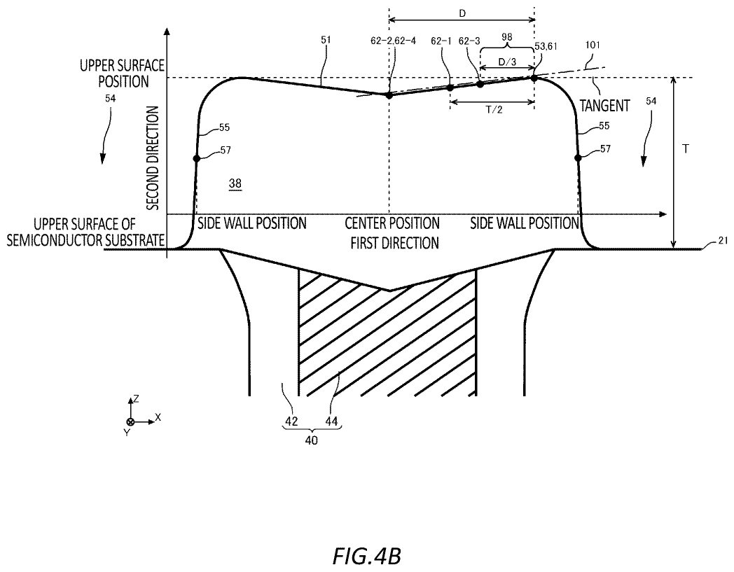

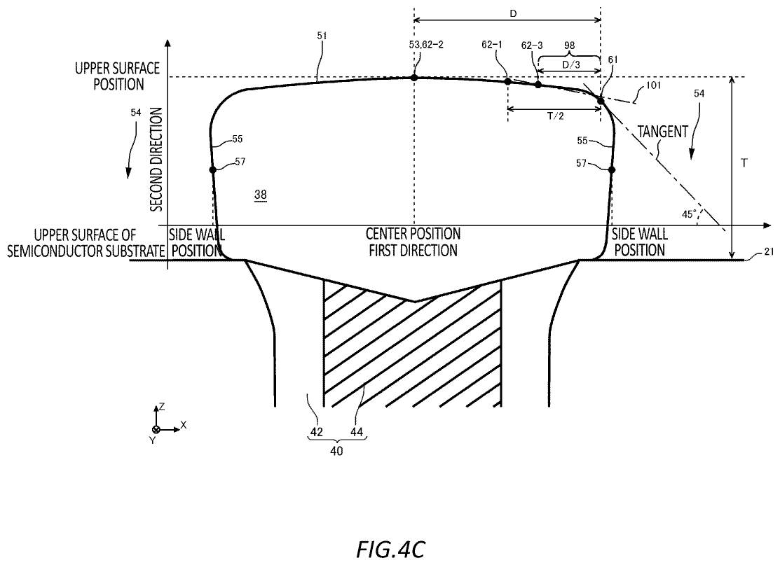

FIG. 4A is a cross-sectional view showing a method for approximating the upper surface 51 of the interlayer dielectric film 38. FIG. 4A shows an XZ cross section traversing the interlayer dielectric film 38 and two contact holes 54 sandwiching the interlayer dielectric film 38. Note that the barrier metal 56, the contact plugs 58, and the emitter electrode 52 are omitted.

A width direction of the contact holes 54 is defined as a first direction. For example, the first direction is a direction along which the contact holes 54 and the interlayer dielectric films 38 are alternately arranged. In the case where at least one of the contact hole 54 or the interlayer dielectric film 38 is provided so as to extend on an XY plane, the first direction may be a direction perpendicular to the extending direction of the contact hole 54 or the interlayer dielectric film 38. On a cross section traversing the contact hole 54, the first direction may be a direction that is parallel to the upper surface 21 of the semiconductor substrate 10 and that extends from a center of the interlayer dielectric film 38 in the X axis direction toward the contact hole 54. The first direction in FIG. 4A matches the X axis direction.

A direction perpendicular to the upper surface 21 of the semiconductor substrate 10 is defined as a second direction. The second direction matches the Z axis direction and the depth direction. An upper surface position 53 of the interlayer dielectric film 38 in the second direction may be a highest position of the upper surface 51 of the interlayer dielectric film 38 in the second direction. Further, as a position of the side wall 55 of the contact hole 54 in the first direction (a representative value of the position of the side wall 55 in the first direction), it is acceptable to use the position (a side wall position) in the first direction of a midpoint 57 of the side wall 55 in a height direction (the second direction). The midpoint 57 of the side wall 55 is a point on the side wall 55 positioned at a half of the height of the interlayer dielectric film 38.

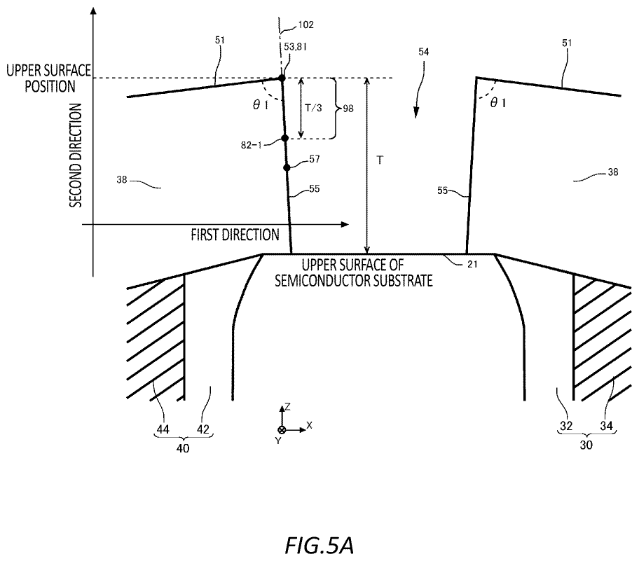

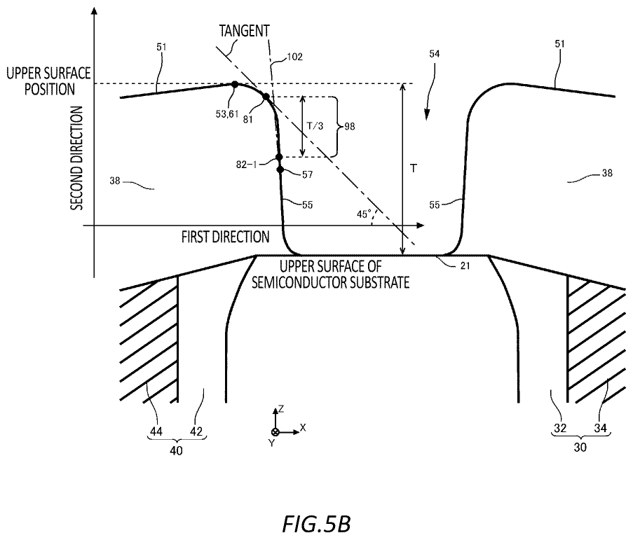

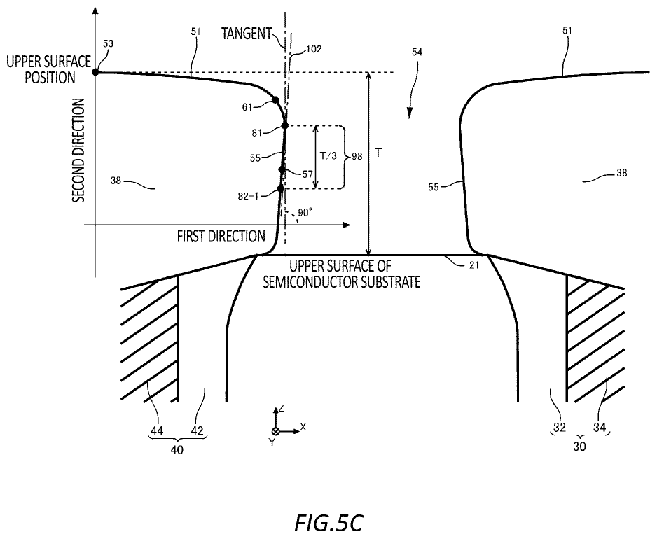

The angle θ1 may be determined by an angle formed by an approximate straight line 101 approximating the upper surface 51 of the interlayer dielectric film 38 and an approximate straight line 102 (see FIG. 5A, for example) approximating the side wall 55 of the contact hole 54. As each of the approximate straight lines 101 and 102, it is acceptable to use a regression line calculated from a predetermined range 98 of the upper surface 51 of the interlayer dielectric film 38 or the side wall 55 of the contact hole 54. With FIG. 4A, an example of calculating the approximate straight line 101 will be explained. FIG. 4A shows the range 98 corresponding to the approximate straight line 101. An example of calculating the approximate straight line 102 will be explained with FIG. 5A and the like. The regression line may be calculated by using a least squares method. The predetermined range 98 may be between two points described below.

When the upper surface 51 of the interlayer dielectric film 38 is to be approximated, the two points defining the range 98 for drawing the regression line may be a first point 61 in the vicinity of the corner of the interlayer dielectric film 38 and a second point 62 apart from the point. If the corner of the interlayer dielectric film 38 has no roundness, and the position of the corner is clear, it is acceptable to use the corner as the first point 61. FIG. 4A shows a situation in which the position of the corner is clear, and the corner is used as the first point 61. The first point 61 in the case where the position of the corner of the interlayer dielectric film 38 is unclear will be explained later.

As the second point 62, it is acceptable to use a position on the upper surface 51 that is positioned apart from the first point 61 along the first direction by a predetermined distance. For example, as the second point 62, it is acceptable to use a position 62-1 on the upper surface 51 that is apart from the first point 61 along the first direction by a distance corresponding to a thickness T of the interlayer dielectric film 38. For example, the distance corresponding to the thickness T may be T/2, may be T/3, may be T/4, or may be other values smaller than T. The distance corresponding to the thickness T in the present example is T/2. The thickness T is a distance between the upper surface 21 of the semiconductor substrate 10 and the upper surface position 53 of the interlayer dielectric film 38.

Alternatively, as the second point 62, it is acceptable to use a position 62-2 on the upper surface 51 of the interlayer dielectric film 38 at a center position of the interlayer dielectric film 38 in the first direction (the center position between the midpoint 57 of one side wall 55 and the midpoint 57 of another side wall 55).

D denotes a distance from the first point 61 to the position 62-2 in the first direction. As the second point 62, it is acceptable to use a position 62-3 on the upper surface 51 that is apart from the first point 61 along the first direction by a distance corresponding to the distance D. For example, the distance corresponding to the distance D may be D/2, may be D/3, may be D/4, may be D/5, may be D/10, or may be other values smaller than D. The distance corresponding to the distance D in the present example is D/3.

Alternatively, as the second point 62, it is acceptable to use a lowest point 62-4 of the upper surface 51 of the interlayer dielectric film 38 that is positioned closest to the semiconductor substrate 10 (a negative side in the second direction). In FIG. 4A, the position 62-2 and the lowest point 62-4 are the same position. FIG. 4A indicates that the range 98 is between the first point 61 and the position 62-3 and that the regression line of the upper surface 51 of the interlayer dielectric film 38 in the range 98 is used as the approximate straight line 101.

As the first point 61 and the second point 62 defining the range 98, it is acceptable to use two arbitrary points arranged in the range from the position of the corner to the position 62-3. In another example, as the first point 61, it is acceptable to use a point on the upper surface 51 to which the distance from the position of the corner is equal to or shorter than 10 nm. As the second point 62, it is acceptable to use an arbitrary point on the upper surface 51 in the range from the first point 61 to the position 62-2. The distance between the first point 61 and the second point 62 may be equal to or shorter than 10 nm. The distance may be equal to or longer than 1 nm.

The regression line may be a straight line of which a coefficient of determination in the range 98 is equal to or larger than 0.9. It is possible to calculate a coefficient of determination R by using an expression presented below, for example.

R²=1−RSS/TSS

In the range 98, positions on the upper surface 51 in the second direction at n sampling points arranged at regular intervals in the first direction are defined as y1, y2, . . . and yn. Further, at the sampling points, positions on the approximate straight line 101 in the second direction are defined as f1, f2, . . . and fn. An average value of y1 to yn is defined as ya. RSS is a value obtained by adding together (yi−fi)² from i=1 to n. TSS is a value obtained by adding together (yi−ya)² from i=1 to n. For example, n may be 10 or may be a value larger than 10. Further, it is acceptable to select the first point 61 and the second point 62 so that the coefficient of determination is equal to or larger than 0.9. From within the range 98 that makes the coefficient of determination equal to or larger than 0.9, it is acceptable to select the first point 61 and the second point 62 so as to maximize the length of the range 98. As a result, it is possible to approximate the upper surface 51 of the interlayer dielectric film 38 with excellent precision.

FIG. 4B is a cross-sectional view showing another method for approximating the upper surface 51 of the interlayer dielectric film 38. The interlayer dielectric film 38 in the present example has a roundness (R) at the corner. If an end portion of the interlayer dielectric film 38 has no corner or if the position of the corner is undetermined or the like, it is necessary to determine the first point 61 that substitutes for the corner. FIG. 4B shows a method for approximating the upper surface 51 of the interlayer dielectric film 38 by determining the first point 61, in the case where the center position of the upper surface 51 in the first direction has a dip, and the position of the corner is undeterminable.

As a position of the first point 61, it is acceptable to use, in the first direction, the position at which the gradient of a tangent of the upper surface 51 of the interlayer dielectric film 38 is zero. When there are a plurality of positions at which the gradient is zero, it is acceptable to use, as the first point 61, the position closest to the side wall of the contact hole 54. In the drawing, the tangent is the same as the dotted line representing the upper surface position.

The second point 62 may be the position 62-1, may be the position 62-2, may be the position 62-3, or may be the lowest point 62-4 described above. FIG. 4B indicates that the range 98 is between the first point 61 and the position 62-3 and that the regression line of the upper surface 51 of the interlayer dielectric film 38 in the range 98 is used as the approximate straight line 101.

In the present example also, as the first point 61 and the second point 62, it is acceptable to use two arbitrary points arranged in the range from the position at which the gradient of the tangent is zero to the position 62-3. In another example, as the first point 61, it is acceptable to use a point on the upper surface 51 to which the distance from the position at which the gradient of the tangent is zero is equal to or shorter than 10 nm. As the second point 62, it is acceptable to use an arbitrary point on the upper surface 51 in the range from the first point 61 to the position 62-2. The distance between the first point 61 and the second point 62 may be equal to or shorter than 10 nm. The distance may be equal to or longer than 1 nm. Further, on the coefficient of determination, the same condition as that in the situation in FIG. 4A may be imposed.

FIG. 4C is a cross-sectional view showing yet another method for approximating the upper surface 51 of the interlayer dielectric film 38. As for the interlayer dielectric film 38 in the present example, the height (the position in the second direction) of the upper surface 51 of the interlayer dielectric film 38 decreases from the position 62-2 toward the side wall 55 of the contact hole 54. Further, the interlayer dielectric film 38 in the present example also has the roundness (R) at the corner. FIG. 4C shows a method for approximating the upper surface 51 of the interlayer dielectric film 38 in that situation, by determining the first point 61.

As a position of the first point 61, it is acceptable to use a position on the upper surface 51 at which the angle formed by the tangent of the upper surface 51 of the interlayer dielectric film 38 and a first direction axis is 45 degrees. In other words, as the first point 61, it is acceptable to use the position on the upper surface 51 at which the absolute value of the gradient of the tangent of the upper surface 51 of the interlayer dielectric film 38 is 1. In the present example, the first point 61 is defined as a position on the upper surface 51 at which the gradient of the tangent is −1 in the vicinity of the side wall on the left side (the negative side in the first direction) of the contact hole 54. When there are a plurality of such positions, it is acceptable to use, as the first point 61, the position closest to the side wall of the contact hole 54 in the first direction. In the drawing, the tangent is shown with a dash dotted line.

The second point 62 may be the position 62-1, may be the position 62-2, may be the position 62-3, or may be the upper surface position 53 described above. FIG. 4C indicates that the range 98 is between the first point 61 and the position 62-3 and that the regression line of the upper surface 51 of the interlayer dielectric film 38 in the range 98 is used as the approximate straight line 101.

In the present example also, as the first point 61 and the second point 62, it is acceptable to use two arbitrary points arranged in the range from the position at which the angle formed by the tangent and the first direction axis is 45 degrees to the position 62-3. In another example, as the first point 61, it is acceptable to use a point on the upper surface 51 to which the distance from the position at which the angle formed by the tangent and the first direction axis is 45 degrees is equal to or shorter than 10 nm. As the second point 62, it is acceptable to use an arbitrary point on the upper surface 51 in the range from the first point 61 to the position 62-2. The distance between the first point 61 and the second point 62 may be equal to or shorter than 10 nm. The distance may be equal to or longer than 1 nm. Further, on the coefficient of determination, the same condition as that in the situation in FIG. 4A may be imposed.

In FIG. 4C, although the gate conductive portion 44 has a dip, the upper surface 51 of the interlayer dielectric film 38 bulges upward. In an example, this shape is formed by performing reflow a plurality of times. At the reflow for the first time, the dip in the upper surface 51 caused by the dip in the gate conductive portion 44 is mitigated. At the reflow for the second time, the vicinity of the corners of the interlayer dielectric film 38 moves downward while becoming round. As a result, the shape shown in FIG. 4C is achieved. Note that the gate conductive portion 44 may not have a dip.

FIG. 5A is a cross-sectional view showing a method for approximating the side wall 55 of a contact hole 54. In the present example, a situation in which the position of the corner of the interlayer dielectric film 38 is clear will be described, similarly to FIG. 4A. FIG. 5A shows an XZ cross section traversing two interlayer dielectric films 38 and a contact hole 54 between the two interlayer dielectric films 38. Note that the barrier metal 56, the contact plugs 58, and the emitter electrode 52 are omitted. The first direction, the second direction, the upper surface position 53, the midpoint 57, and the thickness T are the same as those in FIG. 4A and the like.

When the side wall 55 of the contact hole 54 is to be approximated, the two points defining the range 98 for drawing the regression line may be a first point 81 in the vicinity of the corner of the interlayer dielectric film 38 and a second point 82 apart from the point. If the corner of the interlayer dielectric film 38 has no roundness, and the position of the corner is clear, it is acceptable to use the corner as the first point 81. FIG. 5A shows a situation in which the position of the corner is clear, and the corner is used as the first point 81. The first point 81 shown in FIG. 5A may be equal to the position of the first point 81 shown in FIG. 4A. The first point 81 in the case where the position of the corner of the interlayer dielectric film 38 is unclear will be explained later.

As the second point 82, it is acceptable to use a position on the side wall 55 that is positioned apart from the first point 81 along the second direction by a predetermined distance. For example, as the second point 82, it is acceptable to use a position 82-1 on the side wall 55 that is apart from the first point 81 along the second direction by a distance corresponding to the thickness T of the interlayer dielectric film 38. For example, the distance corresponding to the thickness T may be T/2, may be T/3, may be T/4, may be T/5, may be T/10, or may be other values smaller than T. The distance corresponding to the thickness T in the present example is T/3. Alternatively, it is acceptable to use the midpoint 57 as the second point 82. FIG. 5A indicates that the range 98 is between the first point 81 and the position 82-1 in the second direction and that the regression line of the side wall 55 of the contact hole 54 in the range 98 is used as the approximate straight line 102.

As the first point 81 and the second point 82 defining the range 98, it is acceptable to use two arbitrary points arranged in the range from the position of the corner to the position 82-1. In another example, as the first point 81, it is acceptable to use a point on the side wall 55 to which the distance from the position of the corner is equal to or shorter than 10 nm. As the second point 82, it is acceptable to use a point on the side wall 55 in the range from the first point 81 to the midpoint 57. The distance between the first point 81 and the second point 82 may be equal to or shorter than 10 nm. The distance may be equal to or longer than 1 nm.

In the present example also, the regression line may be a straight line of which the coefficient of determination in the range 98 is equal to or larger than 0.9. Further, it is acceptable to select the first point 81 and the second point 82 so that the coefficient of determination is equal to or larger than 0.9. From within the range 98 that makes the coefficient of determination equal to or larger than 0.9, it is acceptable to select the first point 81 and the second point 82 so as to maximize the length of the range 98. As a result, it is possible to approximate the side wall 55 of the contact hole 54 with excellent precision.

FIG. 5B is a cross-sectional view showing another method for approximating the side wall 55 of the contact hole 54. The interlayer dielectric film 38 in the present example has the roundness (R) at the corner. If an end portion of the interlayer dielectric film 38 has no corner or if the position of the corner is undetermined or the like, it is necessary to determine the first point 81 that substitutes for the corner. FIG. 5B shows a method for approximating the side wall 55 of the contact hole 54 by determining the first point 81, in the case where, similarly to FIG. 4B, the center position of the upper surface 51 in the first direction has a dip, and the position of the corner is undeterminable.

As the first point 81, It is acceptable to use a position on the side wall 55 at which, between the midpoint 57 and the upper surface position 53, the angle formed by the tangent of the side wall 55 of the contact hole 54 and the first direction axis is 45 degrees. In other words, as the first point 81, it is acceptable to use the position on the side wall 55 at which the absolute value of the gradient of the tangent of the side wall 55 of the contact hole 54 is 1. In the present example, the first point 81 is defined as a position on the side wall 55 at which the gradient of the tangent is −1 in the vicinity of the side wall on the left side (the negative side in the first direction) of the contact hole 54. When there are a plurality of such positions, it is acceptable to use, as the first point 81, the position farthest from the contact hole 54 in the first direction. In the drawing, the tangent is shown with a dash dotted line.

The second point 82 may be the position 82-1 described above or may be the midpoint 57. FIG. 5B indicates that the range 98 is between the first point 81 and the position 82-1 and that the regression line of the side wall 55 of the contact hole 54 in the range 98 is used as the approximate straight line 102.

In the present example also, as the first point 81 and the second point 82, it is acceptable to use two arbitrary points arranged in the range from the position at which the angle formed by the tangent and the first direction axis is 45 degrees to the position 82-1. In another example, as the first point 81, it is acceptable to use a point on the side wall 55 to which the distance from the abovementioned position is equal to or shorter than 10 nm. As the second point 82, it is acceptable to use a point on the side wall 55 in the range from the first point 81 to the midpoint 57. The distance between the first point 81 and the second point 82 may be equal to or shorter than 10 nm. The distance may be equal to or longer than 1 nm. Further, on the coefficient of determination, the same condition as that in the situation in FIG. 4A may be imposed.

FIG. 5C is a cross-sectional view showing yet another method for approximating the side wall 55 of the contact hole 54. The shape of the contact hole 54 in the present example is inversely tapered. In other words, the opening width becomes larger as the distance to the upper surface 21 of the semiconductor substrate 10 decreases. Further, the interlayer dielectric film 38 in the present example has the roundness (R) at the corner. Similarly to FIG. 4C, FIG. 5C shows a method for approximating the side wall 55 of the contact hole 54 by determining the first point 81, in the case where the height of the upper surface 51 of the interlayer dielectric film 38 decreases from the position 62-2 toward the side wall 55 of the contact hole 54, and the corner of the interlayer dielectric film 38 has a roundness.

As the first point 81, It is acceptable to use a position on the side wall 55 at which the angle formed by the tangent of the side wall 55 of the contact hole 54 and the first direction axis is 90 degrees. In other words, as the first point 81, it is acceptable to use the position on the side wall 55 at which the gradient of the tangent of the side wall 55 of the contact hole 54 is infinite. When there are a plurality of such positions, it is acceptable to use, as the first point 81, the position highest on the positive side in the second direction. In the drawing, the tangent is shown with a dash dotted line.

The second point 82 may be the position 82-1 described above or may be the midpoint 57. FIG. 5C indicates that the range 98 is between the first point 81 and the position 82-1 and that the regression line of the side wall 55 of the contact hole 54 in the range 98 is used as the approximate straight line 102.

In the present example also, as the first point 81 and the second point 82, it is acceptable to use two arbitrary points arranged in the range from the position at which the angle formed by the tangent and the first direction axis is 90 degrees to the position 82-1. In another example, as the first point 81, it is acceptable to use a point on the side wall 55 to which the distance from the abovementioned position is equal to or shorter than 10 nm. As the second point 82, it is acceptable to use a point on the side wall 55 in the range from the first point 81 to the midpoint 57. The distance between the first point 81 and the second point 82 may be equal to or shorter than 10 nm. The distance may be equal to or longer than 1 nm. Further, on the coefficient of determination, the same condition as that in the situation in FIG. 4A may be imposed.

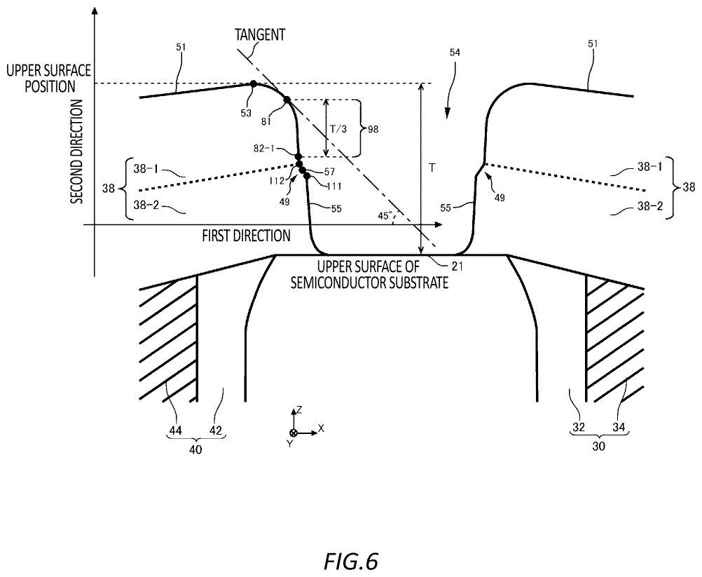

FIG. 6 is a cross-sectional view showing yet another method for approximating the side wall 55 of the contact hole 54. Although FIG. 6 is an enlarged diagram similar to FIG. 5B, the interlayer dielectric film 38 in the present example includes two layers such as an interlayer dielectric film 38-1 and an interlayer dielectric film 38-2. For this reason, stepped portions 49 are formed in a vicinity of centers of the side wall 55 of the contact hole 54.

When the range 98 described above includes a step or unevenness on the side wall 55, it may be impossible to precisely approximate the actual side wall 55. For this reason, it is desirable to determine the first point 81 and the second point 82 so that the stepped portions 49 are not included. In the present example, the midpoint 57 is positioned at the stepped portion 49. Thus, the midpoint 57 may not be used as the second point 82. The stepped portion 49 is a part where a first position 111 and a second position 112 are in close proximity in a direction from a lower end to an upper end of the side wall 55, the first position 111 being a position where the absolute value of the gradient of the tangent of the side wall 55 shifts to decreasing, the second position 112 being a position where the absolute value of the gradient of the tangent of the side wall 55 shifts to increasing. For example, as the stepped portion 49, it is acceptable to use a part where the distance between the first position 111 and the second position 112 in the Z axis direction is equal to or shorter than one fifth of the thickness T. When there are two or more stepped portions 49, it is desirable to determine the first point 81 and the second point 82 described earlier with respect to the stepped portion 49 closest to the first point 81 in the second direction. For example, the first point 81 may be determined from the gradient of the tangent described above. Further, when the position 82-1 is used as the second point 82, it is acceptable to select the distance corresponding to the thickness T described above so as not to include the stepped portion 49 closest to the first point 81.

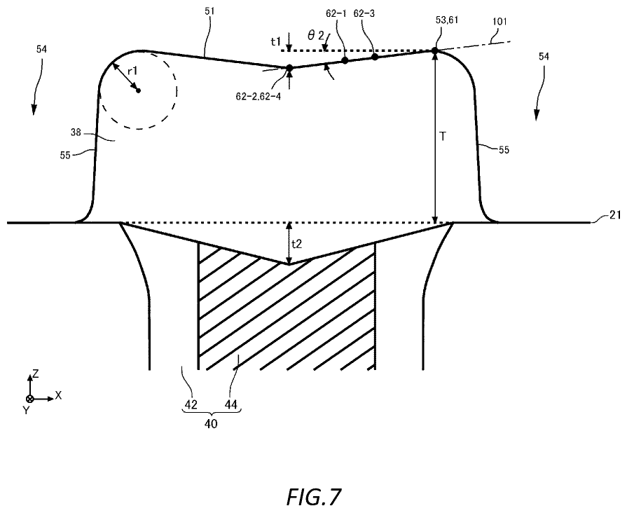

FIG. 7 is an enlarged diagram showing the vicinity of the interlayer dielectric film 38 in FIG. 3. FIG. 7 shows the interlayer dielectric film 38 in the case where the corner has a roundness similarly to FIG. 4B and the like. At least a part of the interlayer dielectric film 38 in the present example is arranged in a position overlapping with the trench conductive portion in the depth direction. The trench conductive portion in the present example is the gate conductive portion 44. This configuration prevents the emitter electrode 52 and the gate conductive portion 44 from having a short circuit. The interlayer dielectric film 38 may be arranged in a position overlapping with the dummy conductive portion 34.

The upper surface of the trench conductive portion in the present example is positioned farther inside the semiconductor substrate 10 relative to the upper surface 21 of the semiconductor substrate 10. In a manufacturing procedure of the semiconductor device 100, polysilicon serving as the trench conductive portion is formed inside the trench, and subsequently, etchback is carried out on extra polysilicon formed in an upper portion relative to the trench. At this time, the polysilicon above the trench is also etched. Further, the polysilicon above the trench may be overetched in many situations, in order to leave no polysilicon on the upper surface 21 of the semiconductor substrate 10 in the mesa portion 60. As a result, the upper surface of the trench conductive portion is positioned farther inside the semiconductor substrate 10 relative to the upper surface 21 of the mesa portion 60.

By adjusting a condition of the etchback, it is possible to make the dip smaller. Alternatively, carrying out Chemical Mechanical Polishing (CMP) instead of the etchback eliminates the dip in the trench conductive portion almost entirely. Note that, even when processing using the CMP method has been performed, the heights of the upper surface of the trench conductive portion and the mesa portion 60 may differ depending on a subsequent process. The position of the upper surface 21 of the semiconductor substrate 10 may be the position of the upper surface 21 highest on the positive side in the Z axis direction and may be the upper surface 21 of the semiconductor substrate 10 in the mesa portion 60. Further, the position of the upper surface of the trench conductive portion may be the position of the upper surface of the trench conductive portion lowest on the negative side in the Z axis direction (a position dipping the most). Further, the upper surface of the trench conductive portion does not need to be parallel to the upper surface 21 of the semiconductor substrate 10.

A position, in the depth direction, of the upper surface 51 of the interlayer dielectric film 38 at an end portion position of the contact hole 54 may be higher than a position, in the depth direction, of the upper surface 51 of the interlayer dielectric film 38 at a position farther from the contact hole 54 than the end portion position. The upper surface 51 of the interlayer dielectric film 38 has a shape reflecting a step of the semiconductor substrate 10. Thus, depending on a positional relationship between the position of the step and the contact hole 54, the height of the interlayer dielectric film 38 at the end portion position of the contact hole 54 may be higher. The dip in the trench conductive portion is an example of the step. Note that, even of the interlayer dielectric film 38 not overlapping with the trench conductive portion, the upper surface may have the abovementioned positional relationship. For instance, an example thereof is the interlayer dielectric film 38 provided in the dummy trench portion 30 or a gate runner portion (which may include the gate metal layer 50 shown in FIG. 1). The upper surface 51 of the interlayer dielectric film 38 does not need to be parallel to the upper surface 21 of the semiconductor substrate 10.

How much the upper surface of the interlayer dielectric film 38 reflects the shape of the step of the semiconductor substrate 10 is determined by an extent of the step and a reflow state of the interlayer dielectric film 38. For example, although BPSG has excellent reflowability, because the reflowability is lowered when a B concentration or a P concentration is low, the shape of the step is easily reflected. Also, the shape of the step is easily reflected in the case where an interlayer dielectric film 38 other than BPSG having low reflowability is used. In addition, the shape of the step is easily reflected, in the case where the reflow process is not performed or where sufficient time or temperature is not applied thereto. Furthermore, even when the reflow process has been performed, the dip may not completely be restored. In those situations, it is possible to inhibit delamination of the barrier metal 56, by using the angle range described above for the angle θ1. In other words, in the present example, because materials of the interlayer dielectric film 38 are not limited, and no additional process is required, it is possible to enhance degrees of freedom in designing and to also reduce costs.

As the end portion position of the contact hole 54, it is acceptable to use the first point 61 explained with FIG. 4A or FIG. 4B. The position farther from the contact hole 54 than the end portion position may be any one of the position 62-1, the position 62-2, the position 62-3, or the lowest point 62-4 in FIG. 4A or FIG. 4B.

A distance in the depth direction between a maximum height position and a minimum height position of the upper surface 51 of the interlayer dielectric film 38 is defined as t1. The maximum height position is the upper surface position 53 in FIG. 4A and the like. The minimum height position is the lowest point 62-4 in FIG. 4A and the like. The distance t1 may be equal to or longer than 0.05 μm and equal to or shorter than 0.4 μm. A lower limit of the distance t1 may be equal to or longer than 0.1 μm, may be equal to or longer than 0.15 μm, or may be equal to or longer than 0.2 μm.

A distance between the upper surface of the trench conductive portion and the upper surface 21 of the semiconductor substrate 10 is defined as t2. The distance t2 may be equal to or longer than 0.05 μm and equal to or shorter than 0.4 μm. The upper surface of the trench conductive portion and the upper surface 21 of the semiconductor substrate 10 may be defined as described above. A maximum value may be used as the distance t2. A lower limit of the distance t2 may be equal to or longer than 0.1 μm, may be equal to or longer than 0.15 μm, or may be equal to or longer than 0.2 μm. The distance t1 may be equal to the distance t2 or may be shorter than the distance t2. The distance t1 becomes shorter depending on a reflow state of the interlayer dielectric film 38. The distance t1 may be equal to or longer than 0.1 μm and equal to or shorter than 0.3 μm, or may be equal to or longer than 0.05 μm and equal to or shorter than 0.3 μm.

In an example, the thickness T of the interlayer dielectric film 38 may be 1.0 μm. The thickness T may be a maximum thickness of the interlayer dielectric film 38. A ratio of the distance t2 to the thickness T may be equal to or larger than 0.1 and equal to or smaller than 0.5, or may be equal to or larger than 0.2 and equal to or smaller than 0.4. A ratio of the distance t1 to the thickness T may be equal to or larger than 0.1 and equal to or smaller than 0.5, or may be equal to or larger than 0.2 and equal to or smaller than 0.4.

FIG. 7 shows, with a dotted line, a circle approximating a roundness of a corner formed by the side wall 55 of the contact hole 54 and the upper surface 51 of the interlayer dielectric film 38. A radius of the roundness of the corner may be equal to or smaller than one fourth of the thickness T of the interlayer dielectric film 38. In other words, a radius r1 of the approximating circle may be equal to or smaller than one fourth of the thickness T. When the radius r1 of the roundness of the corner is too large, although the delamination of the barrier metal 56 occurs less easily, an additional process is necessary for forming the roundness. Further, when the mesa portion 60 is narrowed due to miniaturization, it becomes more difficult to increase the radius R1 of the roundness. Further, when the radius R1 becomes larger, the volume of the contact hole 54 becomes larger. Thus, a usage amount of expensive tungsten being a material of the contact plugs 58 may also increase. According to the present example, even when the radius r1 of the roundness is small, it is possible to inhibit delamination of the barrier metal 56 by adjusting the angle θ1. The radius r1 of the roundness may be equal to or smaller than one fifth of the thickness T of the interlayer dielectric film 38 or may be equal to or smaller than one tenth.

An angle formed by the upper surface 51 of the interlayer dielectric film 38 with respect to a plane parallel to the upper surface 21 of the semiconductor substrate 10 is defined as θ2. On the XZ cross section shown in FIG. 7, the angle formed by the upper surface 51 of the interlayer dielectric film 38 with respect to the X axis direction is defined as θ2. As the upper surface 51 of the interlayer dielectric film 38, it is acceptable to use the approximate straight line 101 described above. The angle θ2 may be equal to or larger than 0°, may be equal to or larger than 2°, may be equal to or larger than 4°, may be equal to or larger than 6°, may be equal to or larger than 8°, may be equal to or larger than 10°, may be equal to or larger than 12°, or may be equal to or larger than 14°. The angle θ2 may be equal to or smaller than 20°, may be equal to or smaller than 18°, may be equal to or smaller than 16°, may be equal to or smaller than 14°, may be equal to or smaller than 12°, may be equal to or smaller than 10°, may be equal to or smaller than 8°, or may be equal to or smaller than 6°. A lower limit value and an upper limit value may each arbitrarily be combined in a range causing no conflict. Further, the present example shows the angle θ2 in the case where the interlayer dielectric film 38 has a dip toward the upper surface 21 side of the semiconductor substrate 10; however, as shown in FIG. 4C, the interlayer dielectric film 38 may protrude in a direction away from the upper surface 21 (the positive side on the Z axis). The angle θ2 in that case may also be within the range described above. Note that, although FIG. 7 describes the example of the contact hole 54, the same feature may also be true with other contact holes shown in FIG. 1 and the like.

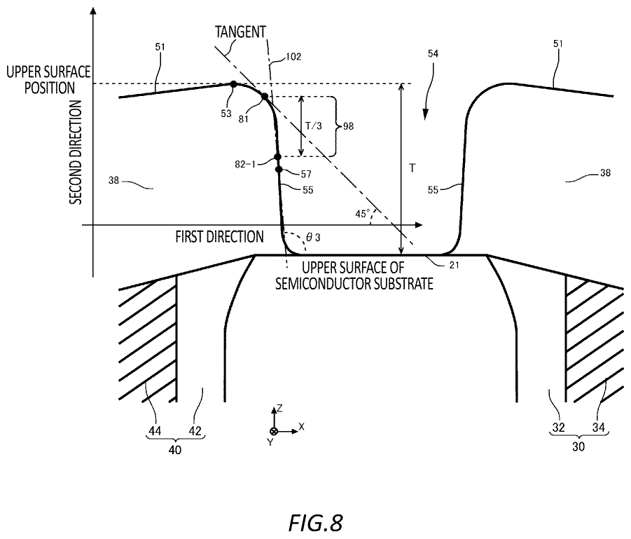

FIG. 8 is an enlarged diagram showing the vicinity of a contact hole 54 in FIG. 3. FIG. 8 also indicates an example in which the interlayer dielectric film 38 has a roundness at the corner. An angle formed by the side wall 55 of the contact hole 54 and the upper surface 21 of the semiconductor substrate 10 will be expressed as θ3. The angle θ3 may be equal to or larger than 90°. In other words, the opening width of the contact hole 54 in the present example is constant or increases upward. That is, a directly-tapered shape.

As a reference (0°), the angle θ3 may use the upper surface 21 of the semiconductor substrate 10 in a range not overlapping with the interlayer dielectric film 38. The side wall 55 of the contact hole 54 may be approximated by the approximate straight line 102 explained with FIG. 5B and the like. Note that, when there is a clear corner at an end portion of the interlayer dielectric film 38, it is acceptable to use the approximate straight line 102 shown in FIG. 5A as the side wall 55.

The angle θ3 may be equal to or smaller than 110°. The smaller the angle θ3 is, the more easily miniaturization is achieved. Further, because the volume of the contact hole 54 becomes smaller, it is possible to reduce the usage amount of expensive tungsten being a material of the contact plugs 58. The angle θ3 may be varied according to an etching condition used at the time of forming the contact hole 54.

The angle θ3 may be equal to or larger than 92°, may be equal to or larger than 94°, may be equal to or larger than 96°, may be equal to or larger than 98°, may be equal to or larger than 100°, may be equal to or larger than 102°, or may be equal to or larger than 104°. The angle θ3 may be equal to or smaller than 108°, may be equal to or smaller than 106°, may be equal to or smaller than 104°, may be equal to or smaller than 102°, may be equal to or smaller than 100°, may be equal to or smaller than 98°, or may be equal to or smaller than 96°. A lower limit value and an upper limit value may each arbitrarily be combined in a range causing no conflict. Further, the angle θ2 and the angle θ3 described above may arbitrarily be combined. Note that, although FIG. 8 describes the example of the contact hole 54, the angle θ3 may also fall in the range described above with other contact holes shown in FIG. 1 and the like.

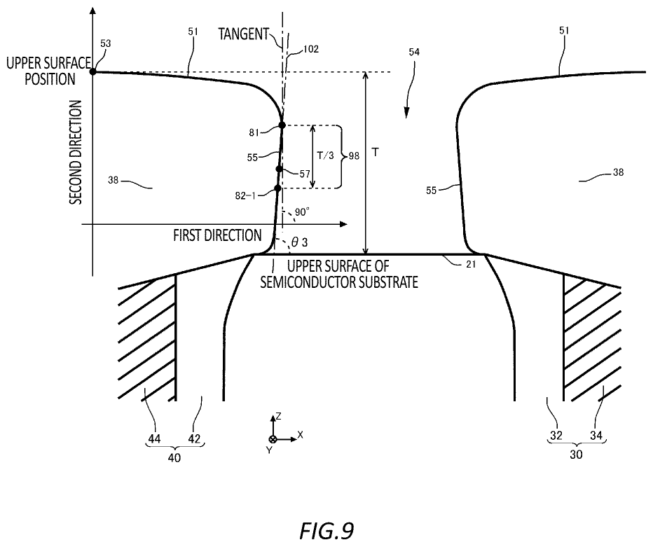

FIG. 9 is an enlarged diagram showing another example of the vicinity of a contact hole 54 in FIG. 3. The angle θ3 in the present example is smaller than 90°. In other words, the contact hole 54 in the present example is inversely tapered. As the side wall 55 of the contact hole 54, it is acceptable to use the approximate straight line 102 in FIG. 5C. In this situation also, it is possible to inhibit delamination of the barrier metal 56, by keeping the angle θ1 in the range described above. The angle θ3 may be equal to or smaller than 85°, may be equal to or smaller than 80°, or may be equal to or smaller than 75°. The angle θ3 may be larger than 70°. Note that, although FIG. 9 describes the example of the contact hole 54, the angle θ3 may also fall in the range described above with other contact holes shown in FIG. 1 and the like.

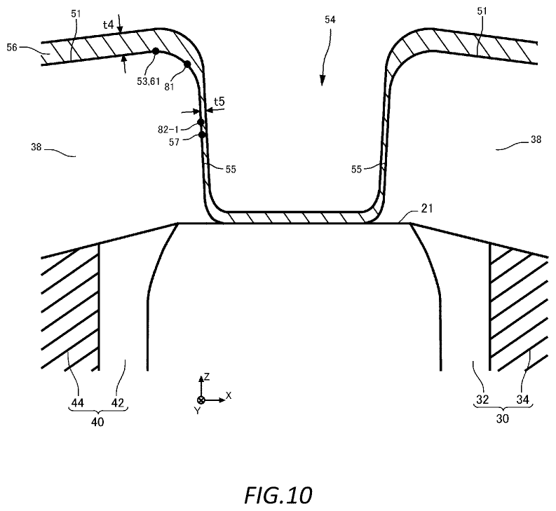

FIG. 10 is an enlarged diagram showing yet another example of the vicinity of a contact hole 54 in FIG. 3. FIG. 10 shows the barrier metal 56 in the vicinity of the contact hole 54. The barrier metal 56 in the present example is provided inside the contact hole 54 and on the upper surface 51 of the interlayer dielectric film 38.

A thickness of the barrier metal 56 on the upper surface 51 of the interlayer dielectric film 38 is defined as t4. The thickness t4 may be equal to or larger than 10 nm and equal to or smaller than 300 nm. A lower limit of the thickness t4 may be equal to or larger than 20 nm, may be equal to or larger than 30 nm, may be equal to or larger than 40 nm, or may be equal to or larger than 50 nm. An upper limit of the thickness t5 may be equal to or smaller than 250 nm, may be equal to or smaller than 200 nm, or may be equal to or smaller than 150 nm. The thickness t4 may be a thickness in a direction perpendicular to the upper surface 51 of the interlayer dielectric film 38. An end portion of the upper surface 51 of the interlayer dielectric film 38 may be the first point 61 explained with FIG. 4B and the like. As the thickness t4, it is acceptable to use any one of a maximum value, a minimum value, or an average value, in a range from the first point 61 on the upper surface 51 of the interlayer dielectric film 38 to any one of the position 62-1, the position 62-2, the position 62-3, or the lowest point 62-4.

A thickness of the barrier metal 56 on the side wall 55 of the contact hole 54 is defined as t5. The thickness t5 may be equal to or larger than 0.5 nm and equal to or smaller than 272 nm. The thickness t5 may be a thickness in a direction perpendicular to the side wall 55 of the contact hole 54. An upper end portion of the side wall 55 of the contact hole 54 may be the first point 81 explained with FIG. 5B and the like. As the thickness t5, it is acceptable to use any one of a maximum value, a minimum value, or an average value, in a range from the first point 81 on the side wall 55 of the contact hole 54 to the position 82-1 or the midpoint 57 on the side wall 55 of the contact hole 54.

A ratio of the thickness t4 to the thickness t5 may be equal to or larger than 1.1 and equal to or smaller than 50. For example, when the barrier metal 56 is formed by sputtering, because the barrier metal 56 does not easily adhere to the side wall 55, the thickness t5 is likely to be smaller than the thickness t4. Further, even when a CVD technique is used, the same film thickness tendency as with sputtering may be exhibited, depending on deposition conditions. Furthermore, when the contact hole 54 has an inversely-tapered shape, the thickness t5 of the barrier metal 56 on the side wall 55 may be small. Meanwhile, as the ratio becomes larger, because the barrier metal 56 has a larger difference in thickness in the vicinity of the corner of the interlayer dielectric film 38, it is feared that delamination of the barrier metal 56 may occur more easily. For these reasons, it is desirable that the abovementioned ratio is not too large. An upper limit of the abovementioned ratio may be equal to or smaller than 40, may be equal to or smaller than 30, may be equal to or smaller than 20, may be equal to or smaller than 15, may be equal to or smaller than 10, or may be equal to or smaller than 5. A lower limit of the abovementioned ratio may be equal to or larger than 2, may be equal to or larger than 3, may be equal to or larger than 4, or may be equal to or larger than 10. It is possible to adjust the abovementioned ratio by adjusting deposition conditions such as deposition pressure, applied power, or a gas flow rate for the sputtering; or deposition pressure or a gas flow rate (ratio) for the CVD technique. In an example, it is possible to decrease the abovementioned ratio by increasing the deposition pressure, because more particles and molecules are scattered. Conversely, it is possible to increase the abovementioned ratio by decreasing the deposition pressure. Note that the gas flow rate ratio denotes a ratio of a flow rate of a carrier gas to a flow rate of a precursor gas in the CVD technique.

In the present example, the angle θ1 may be within the range explained with FIG. 3 or may be outside the range. Regardless of values of the angle θ1, it is possible to inhibit delamination of the barrier metal 56 by adjusting the ratio of the barrier metal 56. Further, the ratio or the film thicknesses of the barrier metal 56 in the present example may be combined with any of the examples of the interlayer dielectric film 38 explained with FIG. 1 to FIG. 9. Note that, although FIG. 10 also describes the example of the contact hole 54, the ratio or the film thicknesses of the barrier metal 56 may also fall in the range described above with other contact holes shown in FIG. 1 and the like.

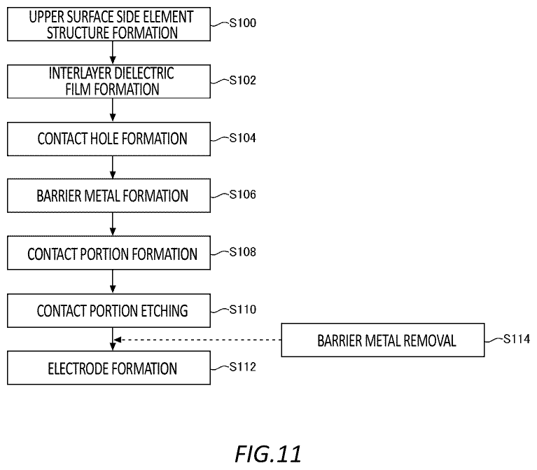

FIG. 11 is a drawing showing an example of a manufacturing process of the semiconductor device 100. FIG. 11 shows a part of the manufacturing process. The manufacturing process includes: an upper surface side element structure forming step S100, an interlayer dielectric film forming step S102, a contact hole forming step S104, a barrier metal forming step S106, a contact portion forming step S108, a contact portion etching step S110, and an electrode forming step S112. The manufacturing process may further include a barrier metal removing step S114.

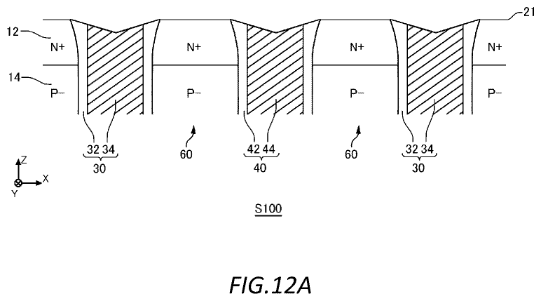

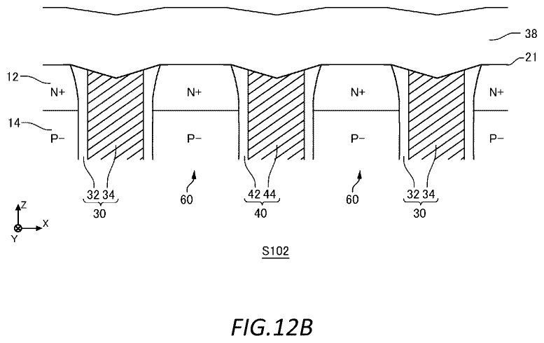

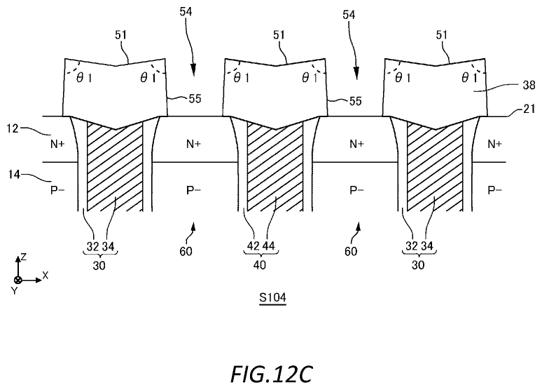

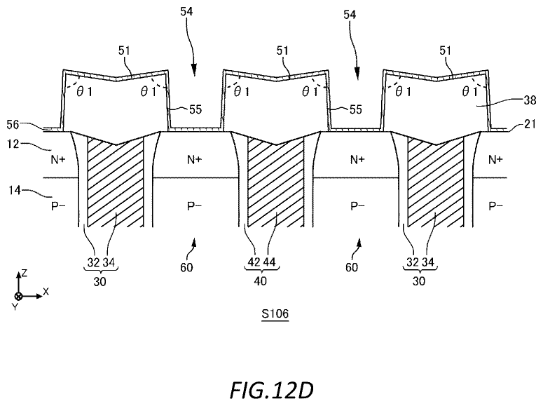

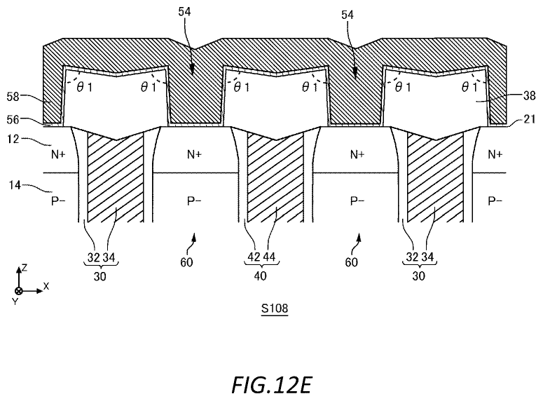

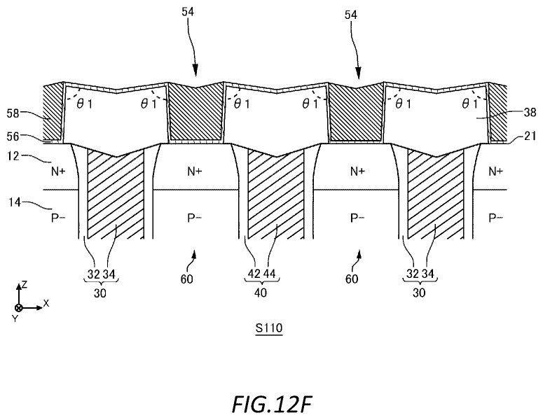

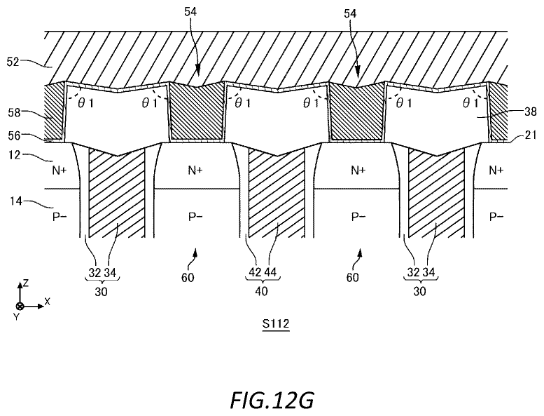

FIG. 12A is a drawing showing an example of the upper surface side element structure forming step S100. The drawings in FIG. 12A and later that show the manufacturing process depict the same range as that in the cross-sectional view shown in FIG. 3. In the upper surface side element structure forming step S100, the various regions and the trench portion are formed on the upper surface 21 side of the semiconductor substrate 10. As described above, the upper surface of the trench conductive portion (the gate conductive portion 44 and the dummy conductive portion 34) may be positioned farther inside the semiconductor substrate 10 relative to the upper surface 21 of the semiconductor substrate 10.

FIG. 12B is a drawing showing an example of the interlayer dielectric film forming step S102. In the interlayer dielectric film forming step S102, the interlayer dielectric film 38 is formed on the upper surface 21 of the semiconductor substrate 10. The upper surface of the interlayer dielectric film 38 reflects the shape of a formation plane. Reflecting the shape of the trench conductive portion, the upper surface of the interlayer dielectric film 38 in the present example has a dip above the trench conductive portion.

As described above, it is possible to adjust degrees of dipping, with the reflow state of the interlayer dielectric film 38. For example, it is possible to reduce a dipping amount by performing the reflow process at a sufficiently high heating temperature (e.g., approximately 1000 degrees). Further, in the case where BPSG is used for the interlayer dielectric film 38, increasing concentrations of boron and phosphorus enhances reflowability and reduces the dipping amount. Note that the dipping amount may not be zero, even when a sufficient reflow process is performed.

FIG. 12C is a drawing showing an example of the contact hole forming step S104. In the contact hole forming step S104, the contact holes 54 are formed in the interlayer dielectric film 38. After the contact holes 54 are formed, the angle θ1 of the interlayer dielectric film 38 may be in the range explained with FIG. 3. Note that, when the ratio of the barrier metal 56 is kept in the range described above, the angle θ1 may be within the range explained with FIG. 3 or may be outside the range.

FIG. 12D is a drawing showing an example of the barrier metal forming step S106. In the barrier metal forming step S106, the barrier metal 56 is formed on the upper surface 51 of the interlayer dielectric film 38 and inside the contact holes 54. The barrier metal 56 may be formed by sputtering or may be formed by using the CVD technique. At this step, the ratio of the thicknesses of the barrier metal 56 may be the values explained with FIG. 10.

FIG. 12E is a drawing showing an example of the contact portion forming step S108. In the contact portion forming step S108, the contact plugs 58 are formed above the barrier metal 56. The contact plugs 58 may be formed by using the CVD technique. In the present step, the contact plugs 58 are also formed above the interlayer dielectric film 38.

FIG. 12F is a drawing showing an example of the contact portion etching step S110. In the contact portion etching step S110, the contact plugs 58 are selectively etched so as to remove the contact plugs 58 above the interlayer dielectric film 38. As a result, the contact plugs 58 filled inside the contact holes 54 are completed.

FIG. 12G is a drawing showing an example of the electrode forming step S112. In the electrode forming step S112, the emitter electrode 52 is formed above the barrier metal 56 and the contact plugs 58.

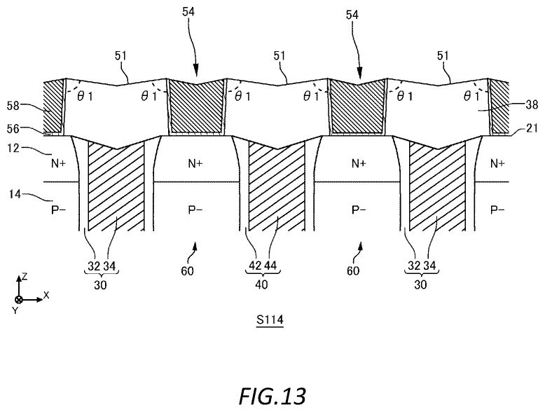

FIG. 13 is a drawing showing an example of a barrier metal removing step S114. In the barrier metal removing step S114, the barrier metal 56 on the upper surface 51 of the interlayer dielectric film 38 is removed. The barrier metal removing step S114 is performed after the contact portion etching step S110. The barrier metal removing step S114 is performed prior to the electrode forming step S112. Even in the case where the barrier metal 56 on the upper surface 51 of the interlayer dielectric film 38 is removed, using the angle θ1 or the ratio of the barrier metal described above makes it possible to prevent the contact portion forming step S108 from being performed while the barrier metal 56 is in a state of being delaminated from the interlayer dielectric film 38.

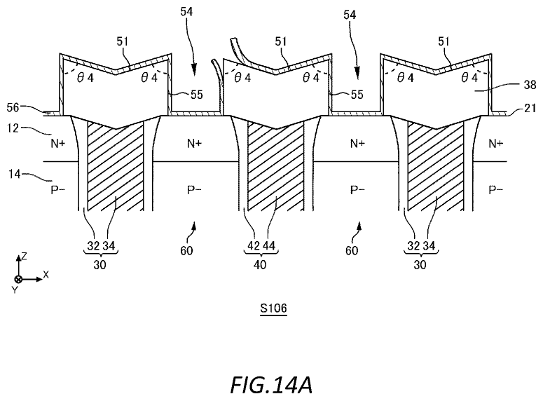

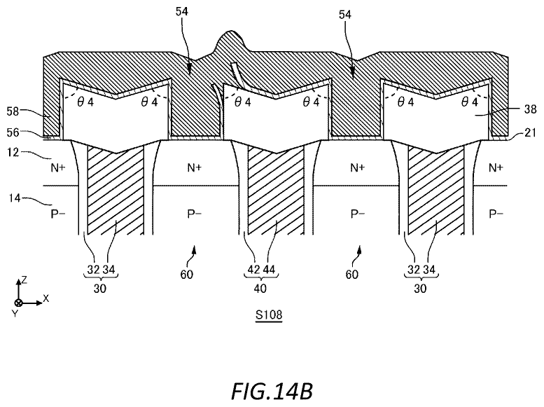

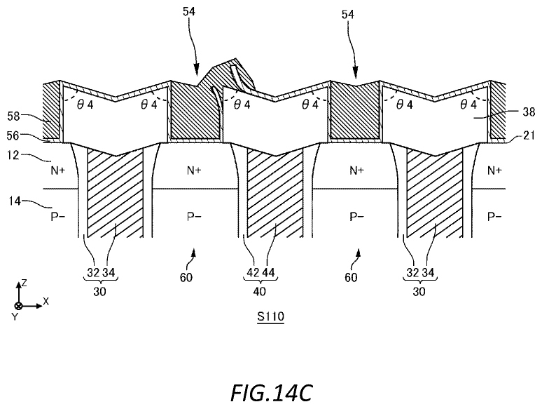

FIG. 14A is a drawing showing a manufacturing process of the semiconductor device 100 in a comparative example. FIG. 14A shows the barrier metal forming step S106 in the comparative example. In the comparative example, an angle θ4 formed by the side wall 55 of the contact hole 54 and the upper surface 51 of the interlayer dielectric film 38 is equal to or smaller than 70°. Thus, great film stress may be imposed on the barrier metal 56 formed in the vicinity of the corner of the interlayer dielectric film 38, and the barrier metal 56 may be delaminated from the interlayer dielectric film 38. In FIG. 14A, the barrier metal 56 is delaminated from the interlayer dielectric film 38 at the corner of the interlayer dielectric film 38 at the center on the negative side on the X axis.

FIG. 14B is a drawing showing the contact portion forming step S108 in a comparative example. In the contact portion forming step S108 in the comparative example also, the contact plugs 58 are formed by using the CVD technique. In an example, the barrier metal 56 has a stacked structure including a Ti film and a TiN film formed thereon. If the barrier metal 56 is delaminated, because the Ti film is exposed to the surface, the Ti film will react with WF₆ gas used in the CVD technique (see Patent Document 5, for example).

FIG. 14C is a drawing showing the contact portion etching step S110 in a comparative example. In the contact portion etching step S110 in the comparative example also, the contact plugs 58 above the interlayer dielectric film 38 are removed. However, in a location where the barrier metal 56 is delaminated, because a contact plug 58 adheres to both surfaces of the barrier metal 56, a volcano phenomenon occurs in which a part protruding more than other parts is formed (see Patent Document 5, for example). Such a protruding part is not desirable because the protruding part will not be removed by etchback and has a possibility of causing a defect in a later process.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that the embodiments to which such alterations or improvements are made can fall within the technical scope of the present invention.

Each process of the operations, procedures, steps, stages, and the like performed by a device, system, program, and method shown in the claims, the specification, and the drawings can be performed in any order as long as the order is not indicated by “prior to,” “before,” and the like and as long as the output from a previous process is not used in a later process. Even if the operational flow is described using phrases such as “first” or “next” for convenience in the claims, the specification, and the drawings, it does not necessarily mean that the process must be performed in this order.

What is claimed is:

1. A semiconductor device comprising:
a semiconductor substrate having an upper surface and a lower surface;
an interlayer dielectric film which is provided on the upper surface of the semiconductor substrate and in which a contact hole is formed;
a barrier metal provided inside the contact hole; and
a contact plug which is, inside the contact hole, filled above the barrier metal, wherein
an angle formed by a side wall of the contact hole and an upper surface of the interlayer dielectric film is larger than 70° and smaller than 90°.

2. The semiconductor device according to claim 1, wherein
the angle formed is larger than 78°.

3. The semiconductor device according to claim 2, wherein
the angle formed is larger than 80°.

4. The semiconductor device according to claim 3, wherein
the angle formed is larger than 84°.

5. The semiconductor device according to claim 1, wherein
a position, in a depth direction, of the upper surface of the interlayer dielectric film at an end portion position of the contact hole is higher than a position, in the depth direction, of the upper surface of the interlayer dielectric film at a position farther from the contact hole than the end portion position.

6. The semiconductor device according to claim 5, wherein
in the depth direction, a distance between a maximum height position and a minimum height position of the upper surface of the interlayer dielectric film is equal to or longer than 0.05 μm and equal to or shorter than 0.4 μm.

7. The semiconductor device according to claim 5, wherein
the semiconductor substrate has a trench portion provided from the upper surface of the semiconductor substrate toward an inside of the semiconductor substrate,
the trench portion includes:
a trench conductive portion provided inside a trench; and
a trench insulating film which insulates the trench conductive portion from the semiconductor substrate,
at least a part of the interlayer dielectric film is arranged in a position overlapping with the trench conductive portion in the depth direction, and
an upper surface of the trench conductive portion is positioned farther inside the semiconductor substrate relative to the upper surface of the semiconductor substrate.

8. The semiconductor device according to claim 7, wherein
a distance between the upper surface of the trench conductive portion and the upper surface of the semiconductor substrate is equal to or longer than 0.05 μm and equal to or shorter than 0.4 μm.

9. The semiconductor device according to claim 1, wherein
an angle formed by the side wall of the contact hole and the upper surface of the semiconductor substrate is equal to or larger than 90°.

10. The semiconductor device according to claim 9, wherein
the angle formed is equal to or smaller than 110°.

11. The semiconductor device according to claim 1, wherein
an angle formed by the side wall of the contact hole and the upper surface of the semiconductor substrate is smaller than 90°.

12. The semiconductor device according to claim 1, wherein
the barrier metal is also provided on the upper surface of the interlayer dielectric film, and
a thickness of the barrier metal on the upper surface of the interlayer dielectric film is equal to or larger than 10 nm and equal to or smaller than 300 nm.

13. The semiconductor device according to claim 12, wherein
a ratio of the thickness of the barrier metal on the upper surface of the interlayer dielectric film to a thickness of the barrier metal on the side wall of the contact hole is equal to or larger than 1.1 and equal to or smaller than 50.

14. The semiconductor device according to claim 1, wherein
a radius of a roundness of a corner formed by the side wall of the contact hole and the upper surface of the interlayer dielectric film is equal to or smaller than one fourth of a thickness of the interlayer dielectric film.

15. The semiconductor device according to claim 1, wherein
the semiconductor substrate has:
a drift region of a first conductivity type;
a channel region of a second conductivity type provided on a side of the upper surface of the semiconductor substrate relative to the drift region; and
a high concentration region of the first conductivity type provided on the side of the upper surface of the semiconductor substrate relative to the channel region, exposed at the upper surface of the semiconductor substrate, and having a higher doping concentration than the drift region, and
at least a part of the contact hole is provided above the high concentration region.

16. A semiconductor device comprising:
a semiconductor substrate having an upper surface and a lower surface;
an interlayer dielectric film which is provided on the upper surface of the semiconductor substrate and in which a contact hole is formed;
a barrier metal provided on the upper surface of the interlayer dielectric film and inside the contact hole; and
a contact plug which is, inside the contact hole, filled above the barrier metal, wherein
a ratio of a thickness of the barrier metal on the upper surface of the interlayer dielectric film to a thickness of the barrier metal on a side wall of the contact hole is equal to or larger than 1.1 and equal to or smaller than 50.

17. A manufacturing method of a semiconductor device, comprising:
forming an interlayer dielectric film on an upper surface of a semiconductor substrate;
forming a contact hole in the interlayer dielectric film;
forming a barrier metal on an upper surface of the interlayer dielectric film and inside the contact hole; and
forming a contact plug above the barrier metal, wherein
a ratio of a thickness of the barrier metal on the upper surface of the interlayer dielectric film to a thickness of the barrier metal on a side wall of the contact hole is equal to or larger than 1.1 and equal to or smaller than 50.

18. The manufacturing method of a semiconductor device according to claim 17, comprising:
removing the barrier metal on the upper surface of the interlayer dielectric film after the forming of the contact plug.

19. The semiconductor device according to claim 6, wherein
the semiconductor substrate has a trench portion provided from the upper surface of the semiconductor substrate toward an inside of the semiconductor substrate,
the trench portion includes:
a trench conductive portion provided inside a trench; and
a trench insulating film which insulates the trench conductive portion from the semiconductor substrate,
at least a part of the interlayer dielectric film is arranged in a position overlapping with the trench conductive portion in the depth direction, and
an upper surface of the trench conductive portion is positioned farther inside the semiconductor substrate relative to the upper surface of the semiconductor substrate.

20. The semiconductor device according to claim 2, wherein
an angle formed by the side wall of the contact hole and the upper surface of the semiconductor substrate is equal to or larger than 90°.
